(19) United States
(12) Patent Application Publication
(10) Pub. No.: US 2026/0107550 A1
(43) Pub. Date: Apr. 16, 2026

(54) SEMICONDUCTOR DEVICES AND METHODS TO REDUCE CONTACT RESISTIVITY IN SEMICONDUCTOR DEVICES

(71) Applicant: Tokyo Electron Limited, Tokyo (JP)

(72) Inventors: Sara Otsuki, Albany, NY (US); Hidenori Chin, Tokyo (JP); Takashi Sakuma, Yamanashi (JP)

(21) Appl. No.: 18/916,972

(22) Filed: Oct. 16, 2024

(51) Int. Cl. H01L 29/49; H01L 29/423; H01L 29/47

(52) U.S. Cl. CPC H10D 64/664; H10D 64/518; H10D 64/64

(57) ABSTRACT

Embodiments of semiconductor devices and methods are provided for reducing the resistivity of contact structures used in semiconductor devices. In the disclosed embodiments, an improved silicidation process is used to reduce the contact resistivity between an overlying metal plug and an underlying silicon-containing layer. The improved silicidation process reduces contact resistivity by forming a thin barrier metal silicide on an underlying silicon-containing layer before a thicker metal layer is deposited onto the barrier metal silicide and heated to form a second metal silicide above the barrier metal silicide. The combination of the barrier metal silicide and the second metal silicide provides a metal silicide-to-semiconductor contact between the overlying metal plug and the underlying silicon-containing layer with reduced contact resistivity.

### TECHNICAL FIELD

The present disclosure relates to semiconductor device fabrication. In particular, it provides improved silicidation processes and methods for reducing the contact resistivity in semiconductor devices, such as metal-oxide semiconductor field effect transistor (MOSFET) devices.

### BACKGROUND

Complementary metal-oxide semiconductor (CMOS) technology is commonly used in the fabrication of integrated circuits. CMOS technology utilizes p-type and n-type metal-oxide semiconductor field effect transistors (MOSFETs) in complementary pairs for logic functions. It is desirable to have MOSFETs with a high drive current when the devices are on in order to achieve a low delay when switching the device. In order to achieve a high drive current, various source and drain (source/drain) structures have been employed in order to maximize the drive current of the MOSFETs by imparting strain to the channel region of the device and/or by minimizing the contact resistivity to the source/drain of the MOSFETs.

In many advanced MOSFETs, epitaxial semiconductor layers with high doping are employed in the source/drain regions of the MOSFETs. For instance, highly doped epitaxial silicon (Si), or carbon doped silicon (Si:C), is frequently used in the source/drain regions of n-type MOSFETs (nMOSFET), while highly doped epitaxial germanium doped silicon (SiGe) is frequently used in the source/drain regions of p-type MOSFETs (pMOSFET). In some cases, a self-aligned silicide process (otherwise referred to as a “salicide” process) is performed to convert a portion of the semiconductor material present within the source/drain regions of the MOSFETs into a low-resistivity metal silicide. In a silicidation process, a metal is placed into contact with silicon and heated to a high temperature, which causes the metal atoms and silicon atoms to combine to form a metal silicide compound. Silicidation is conventionally used to provide a conductive contact between the silicon in a semiconductor device and a metal contact. The resulting metal silicide-to-silicon contact provides less contact resistance than provided with a direct metal-to-silicon contact.

Titanium, cobalt and nickel silicides have been used to reduce contact resistance in MOSFET devices. In some cases, different metal silicides may be used in the source/drain regions of nMOSFET and pMOSFET devices due to a better band alignment with the conduction band (for nMOSFET) and valence band (for pMOSFET) of the semiconductor materials used in the source/drain regions. For example, titanium silicides or titanium carbon doped silicides (silicon-carbides) are commonly used for nMOSFET source/drain contacts, while nickel silicides or nickel silicon-germanides are commonly used for pMOSFET source/drain contacts due to the respective band alignments.

FIG. 1 (Prior Art) illustrates a conventional process flow 100 used to form metal silicides in the source/drain regions of a MOSFET device. The process flow 100 begins with the fabrication of a basic MOSFET structure on/within a silicon-based substrate 105 (e.g., Si, SiGe, etc.) in step (a). As shown in FIG. 1, the MOSFET device includes a source (S) region 110 and a drain (D) region 115 formed within the silicon-based substrate 105 with a gate structure formed above the source/drain (S/D) regions of the MOSFET device. The gate structure may generally include a conductive gate (G) layer 120 (e.g., polysilicon) formed above a thin gate oxide 125. Gate spacers 127 are formed on sidewalls of the gate structure to electrically isolate the gate structure from the source/drain contacts (C) subsequently formed in step (f). Shallow trench isolation (STI) regions are provided within the silicon-based substrate 105 to prevent current leakage between adjacent semiconductor devices.

After the basic MOSFET structure is formed, a metal layer 130 (e.g., titanium (Ti), cobalt (Co) or nickel (Ni)) is deposited onto the exposed surfaces of the MOSFET device using conventional deposition techniques in step (b). After metal deposition, a high temperature anneal process is performed in step (c) to form metal silicides 135 at the interface between the metal layer 130 and the gate (G), source (S) and drain (D) regions of the MOSFET device. During the anneal step, the substrate is exposed to a temperature high enough (e.g., a temperature ranging between 400-900° C.) to cause metal atoms from the metal layer 130 to diffuse into the polysilicon of the gate structure and the silicon within the S/D regions, thereby forming metal silicides 135 having lower resistivity than the underlying polysilicon and silicon. After silicidation, a selective etch may be performed to remove the unreacted portions of the metal layer 130 in step (d) before an interlayer dielectric layer (ILD) 140 is deposited in step (e) and etched to form contact holes or vias to the S/D regions of the MOSFET device. The contact holes or vias may then be filled with a metal material (e.g., copper (Cu), tungsten (W), ruthenium (Ru), etc.) in step (f) to form metal contacts (C) that terminate on the metal silicides of the S/D regions. The metal silicides provided within the S/D regions reduce the contact resistance between the bulk metal of the metal contacts (C) and the underlying silicon.

As transistor dimensions continue to shrink in advanced technology nodes, the contact resistance at the source/drain (which is inversely proportional to the contact area) increases accordingly. Although traditional metal silicides (such as titanium, cobalt and nickel silicides) provide low contact resistivity adequate for 3 nm CMOS technology and above, contacts with even lower contact resistivity will be needed to suppress parasitic resistance and ensure high transistor performance in future technology nodes.

Accordingly, it would be desirable to provide new methods to reduce the resistivity of contact structures used in semiconductor devices, such as MOSFET devices.

### SUMMARY

Embodiments of semiconductor devices and methods are provided herein for reducing the resistivity of contact structures used in semiconductor devices. In the disclosed embodiments, an improved silicidation process is used to reduce the contact resistivity between an overlying metal plug and an underlying silicon-containing layer. The improved silicidation process reduces contact resistivity by forming a thin barrier metal silicide on an underlying silicon-containing layer before a thicker metal layer is deposited onto the barrier metal silicide and heated to form a second metal silicide above the barrier metal silicide. The combination of the barrier metal silicide and the second metal silicide provides a metal silicide-to-semiconductor contact between the overlying metal plug and the underlying silicon-containing layer with reduced contact resistivity.

According to one embodiment, a method is provided herein for reducing contact resistivity in a semiconductor device. In general, the method may include depositing a barrier metal layer on an underlying silicon-containing layer and performing a first heat treatment during or after said depositing the barrier metal layer to convert the barrier metal layer into a barrier metal silicide. When the barrier metal layer comprises zirconium (Zr) or hafnium (Hf), for example, the barrier metal silicide may comprise a zirconium silicide (ZrSi) or a hafnium silicide (HfSi). The method may further include depositing a second metal layer on the barrier metal silicide, performing a second heat treatment during or after said depositing the second metal layer to convert a portion of the second metal layer adjacent to the barrier metal silicide into a second metal silicide and forming a metal plug above and in electrical communication with the second metal layer, the second metal silicide, the barrier metal silicide and the underlying silicon-containing layer. When the second metal layer comprises titanium (Ti), cobalt (Co), nickel (Ni) or tungsten (W), the second metal silicide may comprise a titanium silicide (TiSi), a cobalt silicide (CoSi) a nickel silicide (NiSi) or a tungsten silicide (WSi).

The barrier metal silicide and the second metal silicide formed in the method disclosed above provide a lower contact resistivity between the metal plug and the underlying silicon-containing layer than a contact resistivity provided by the second metal silicide alone. In some embodiments, the barrier metal silicide may reduce the contact resistivity between the metal plug and the underlying silicon-containing layer by providing a lower Schottky barrier height than a Schottky barrier height provided by the second metal silicide. In some embodiments, the barrier metal silicide may also prevent metal atoms from the second metal layer from diffusing into the underlying silicon-containing layer during the second heat treatment and forming a metal silicide layer within the underlying silicon-containing layer.

In some embodiments, said depositing the barrier metal layer may comprise depositing a zirconium (Zr) layer having a thickness less than 10 nm on the underlying silicon-containing layer. In such embodiments, said performing the first heat treatment may comprise exposing the zirconium (Zr) layer to a temperature ranging between 400° C. and 550° C. to convert the zirconium (Zr) layer into a zirconium silicide (ZrSi).

In some embodiments, said depositing the second metal layer may comprise depositing a titanium (Ti) layer having a thickness ranging between 2 nm and 15 nm on the zirconium silicide (ZrSi). In such embodiments, said performing the second heat treatment may comprise exposing the titanium (Ti) layer to a temperature ranging between 300° C. and 550° C. to convert a portion of the titanium (Ti) layer adjacent to the zirconium silicide (ZrSi) into a titanium silicide (TiSi).

In some embodiments, the method may further comprise performing a nitridation process to convert an upper surface of the titanium (Ti) layer into a titanium nitride (TiN) layer prior to forming the metal plug. In such embodiments, said forming the metal plug may comprise forming the metal plug in contact with the titanium nitride (TiN) layer. The metal plug may generally comprise a wide variety of metals, including but not limited to, ruthenium (Ru), tungsten (W), copper (Cu) or aluminum (Al).

According to another embodiment, a method is provided herein for reducing contact resistivity in a metal oxide semiconductor field effect transistor (MOSFET) device comprising a gate structure, a source region and a drain region. In general, the method may include depositing a zirconium (Zr) layer on the source region and the drain region of the MOSFET device, annealing the zirconium (Zr) layer to form a zirconium silicide (ZrSi) on the source region and the drain region of the MOSFET device, and depositing a titanium (Ti) layer on the zirconium silicide (ZrSi), wherein said depositing the titanium (Ti) layer comprises depositing the titanium (Ti) layer at a temperature ranging between 300° C. and 550° C. to convert a portion of the titanium (Ti) layer adjacent to the zirconium silicide (ZrSi) into a titanium silicide (TiSi). The method may further include forming a first metal plug above the source region and a second metal plug above the drain region of the MOSFET device, wherein the first metal plug and the second metal plug are electrically coupled to the source region and the drain region of the MOSFET device through the titanium (Ti) layer, the titanium silicide (TiSi) and the zirconium silicide (ZrSi).

The zirconium silicide (ZrSi) and the titanium silicide (TiSi) provide a lower contact resistivity between the first metal plug and the source region of the MOSFET device, and the second metal plug and the drain region of the MOSFET device, than a contact resistivity provided by the titanium silicide (TiSi) alone. In some embodiments, the zirconium silicide (ZrSi) may reduce the contact resistivity between the first metal plug and the source region of the MOSFET device, and the second metal plug and the drain region of the MOSFET device, by providing a lower Schottky barrier height than a Schottky barrier height provided by the titanium silicide (TiSi). In some embodiments, the zirconium silicide (ZrSi) may also prevent titanium atoms from the titanium (Ti) layer from diffusing into the source region and the drain region of the MOSFET device during said depositing the titanium (Ti) layer on the zirconium silicide (ZrSi).

In some embodiments, said depositing zirconium (Zr) layer may comprise depositing the zirconium (Zr) layer to a thickness less than 10 nm on the underlying silicon-containing layer, and said annealing the zirconium (Zr) layer may comprise exposing the zirconium (Zr) layer to a temperature ranging between 400° C. and 550° C. to convert the zirconium (Zr) layer into the zirconium silicide (ZrSi).

In some embodiments, the method may further comprise performing a nitridation process to convert the upper surface of the titanium (Ti) layer into a titanium nitride (TiN) layer prior to forming the first metal plug above the source region and a second metal plug above the drain region of the MOSFET device. In such embodiments, said forming the first metal plug above the source region and the second metal plug above the drain region of the MOSFET device may comprise forming the first metal plug and the second metal plug in contact with the titanium nitride (TiN) layer. The first metal plug and the second metal plug may comprise, for example, ruthenium (Ru), tungsten (W), copper (Cu) or aluminum (Al).

According to yet another embodiment, a semiconductor device having at least one contact structure is provided herein. The at least one contact structure may generally include a metal plug formed above an underlying silicon-containing layer and a silicide region formed between the metal plug and the underlying silicon-containing layer. The silicide region may comprise a zirconium silicide (ZrSi) formed on the underlying silicon-containing layer and a titanium silicide (TiSi) formed on the zirconium silicide (ZrSi). The zirconium silicide (ZrSi) may have a thickness less than 10 nm and the titanium silicide (TiSi) may have a thickness less than 10 nm. The zirconium silicide (ZrSi) and the titanium silicide (TiSi) included within the at least one contact structure may provide a lower contact resistivity between the metal plug and the underlying silicon-containing layer than a contact resistivity provided by the titanium silicide (TiSi) alone.

In some embodiments, the zirconium silicide (ZrSi) may be formed by depositing a zirconium (Zr) layer having a thickness less than 10 nm on the underlying silicon-containing layer and heating the zirconium (Zr) layer to a temperature ranging between 400° C. and 550° C. to convert the zirconium (Zr) layer into the zirconium silicide (ZrSi). In some embodiments, the zirconium (Zr) layer may be deposited to a thickness less than 2 nm. In other embodiments, the zirconium (Zr) layer may be deposited to a thickness less than or equal to 1 nm.

In some embodiments, the at least one contact structure may further comprise a titanium (Ti) layer having a thickness ranging between 2 nm and 15 nm. In such embodiments, the titanium (Ti) layer may be deposited on the zirconium silicide (ZrSi) and heated to a temperature ranging between 300° C. and 550° C., causing silicon atoms from the zirconium silicide (ZrSi) to diffuse into a lower surface of the titanium (Ti) layer to form the titanium silicide (TiSi) on the zirconium silicide (ZrSi). In some embodiments, the zirconium silicide (ZrSi) may prevent titanium atoms from the titanium (Ti) layer from diffusing into the underlying silicon-containing layer when the titanium (Ti) layer is deposited on the zirconium silicide (ZrSi) and heated.

In some embodiments, the at least one contact structure may further comprise a titanium nitride (TiN) layer formed on an upper surface of the titanium (Ti) layer. In such embodiments, the metal plug may be formed in contact with the titanium nitride (TiN) layer. The metal plug may comprise a wide variety of metals such as, but not limited to, ruthenium (Ru), tungsten (W), copper (Cu) or aluminum (Al).

As noted above and described further herein, the present disclosure provides various embodiments of semiconductor devices and methods for reducing the resistivity of contact structures used in semiconductor devices. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (Prior Art) illustrates a conventional process flow used to form metal silicides in the source/drain regions of a MOSFET device.

FIG. 2 is a flowchart diagram illustrating one embodiment of a method that utilizes the techniques disclosed herein to reduce contact resistivity in a semiconductor device.

FIG. 3 provides cross-sectional views through a portion of a semiconductor device, illustrating an improved silicidation process in accordance with one embodiment of the present disclosure.

FIG. 4 is a flowchart diagram illustrating one embodiment of a method that utilizes the techniques disclosed herein to reduce contact resistivity in a metal oxide semiconductor field effect transistor (MOSFET) device.

FIG. 5 illustrates one embodiment of a process flow that utilizes the techniques disclosed herein to reduce contact resistivity in a MOSFET device.

### DETAILED DESCRIPTION

The present disclosure provides various embodiments of semiconductor devices and methods for reducing the resistivity of contact structures used in semiconductor devices. More specifically, an improved silicidation process is used in the disclosed embodiments to reduce the contact resistivity between an overlying metal plug and an underlying silicon-containing layer.

The silicidation process disclosed herein reduces contact resistivity by depositing a relatively thin (e.g., ≤10 nm) barrier metal layer on an underlying silicon-containing layer, and annealing the barrier metal layer to form a barrier metal silicide, before a thicker metal layer (e.g., a titanium (Ti) layer, nickel (Ni) layer, cobalt (Co) layer, tungsten (W) layer, etc., having a thickness ranging between 2 nm to 15 nm) is deposited onto the barrier metal silicide and heated to form a second metal silicide (e.g., a titanium silicide (TiSi), nickel silicide (NiSi), cobalt silicide (CoSi), tungsten silicide (WSi), etc.) above the barrier metal silicide. The combination of the barrier metal silicide and the second metal silicide provides a metal silicide-to-semiconductor contact between the overlying metal plug and the underlying silicon-containing layer with reduced contact resistivity.

In some semiconductor devices, such as n-type metal-oxide semiconductor field effect transistors (nMOSFETs), contact resistance increases exponentially with the Schottky barrier height (SBH) of the metal silicide-to-semiconductor contact formed between the overlying metal plug and the underlying silicon-containing layer. Thus, using metal silicides with lower SBH is one way in which contact resistance can be reduced in such devices. In some embodiments, the barrier metal silicide disclosed herein may reduce the contact resistivity of the metal silicide-to-semiconductor contact by providing a lower SBH than the SBH provided by the second metal silicide alone. The reduction in SBH is achieved by selecting appropriate work function metals, as discussed in more detail below.

The barrier metal silicide also prevents metal atoms from the second metal layer from diffusing into the underlying silicon-containing layer and forming a metal silicide within the underlying silicon-containing layer when the second metal layer is initially deposited or subsequently annealed.

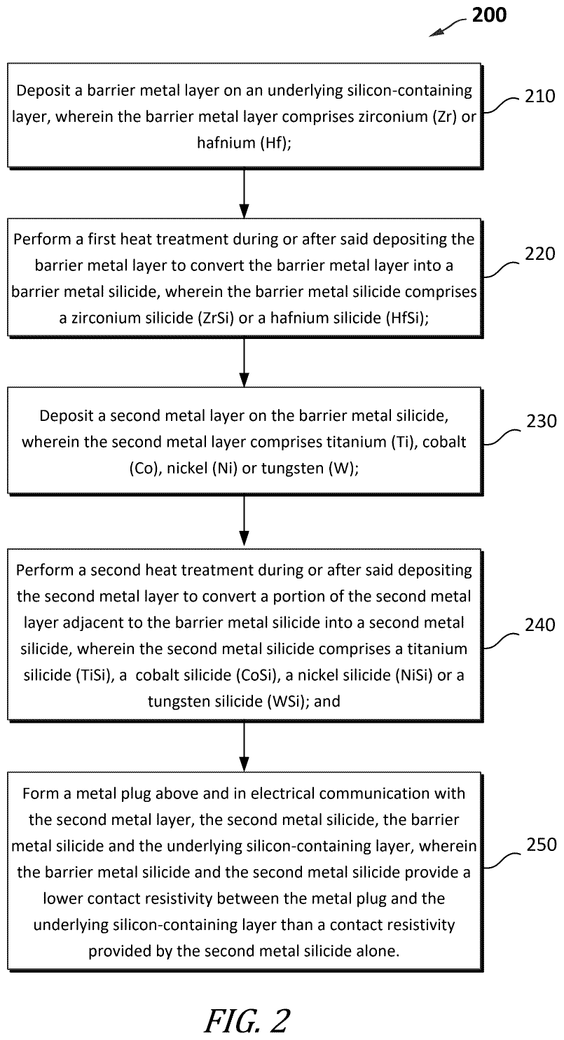

FIG. 2 illustrates one embodiment of a method 200 that utilizes the techniques disclosed herein to reduce contact resistivity in a semiconductor device such as, but not limited to, an nMOSFET device. It will be recognized that the embodiment of the method 200 is merely exemplary and additional methods may utilize the techniques disclosed herein to reduce contact resistance in other semiconductor devices, such as pMOSFET devices. Further, additional processing steps may be added to the method 200 as the steps described are not intended to be exclusive. Moreover, the order of the steps is not limited to the order shown in the figures as different orders may occur and/or various steps may be performed in combination or at the same time.

As shown in FIG. 2, the method 200 may generally begin by depositing a barrier metal layer on an underlying silicon-containing layer (in step 210). The barrier metal layer deposited in step 210 may be a relatively thin layer. For example, the barrier metal layer may have a thickness less than or equal to 10 nm, less than or equal to 2 nm or less than or equal to 1 nm. In the embodiment shown in FIG. 2, the barrier metal layer deposited in step 210 comprises a relatively thin layer of zirconium (Zr) or hafnium (Hf). However, other metals having relatively low work function may also be used to form the barrier metal layer, as described in more detail above. The method 200 further includes performing a first heat treatment (in step 220) to convert the barrier metal layer into a barrier metal silicide. The first heat treatment may be performed during the deposition of the barrier metal layer, or after the barrier metal layer deposition as a post-deposition anneal. During the first heat treatment, the barrier metal layer and the underlying silicon-containing layer are exposed to a high temperature ranging between 400° C. and 550° C. to convert the barrier metal layer into the barrier metal silicide. When the barrier metal layer is zirconium (Zr) or hafnium (Hf), the barrier metal silicide formed on the underlying silicon-containing layer in step 220 may be a zirconium silicide (ZrSi) or a hafnium silicide (HfSi).

After the barrier metal silicide is formed, the method 200 may deposit a second metal layer on the barrier metal silicide (in step 230). The second metal layer deposited in step 230 may generally be thicker than the barrier metal layer. For example, the second metal layer may have a thickness ranging between 2 nm and 15 nm. In the embodiment shown in FIG. 2, the second metal layer deposited in step 230 comprises titanium (Ti), cobalt (Co), nickel (Ni) or tungsten (W). However, other metals may also be used to form the second metal layer, as described in more detail above. The method 200 further includes performing a second heat treatment to convert a portion of the second metal layer adjacent to the barrier metal silicide into a second metal silicide (in step 240). Like the first heat treatment, the second heat treatment may be performed during the deposition of the second metal layer, or after the second metal layer deposition as a post-deposition anneal.

During the second heat treatment, the second metal layer, the barrier metal layer and the underlying silicon-containing layer are exposed to a high temperature ranging between 300° C. and 550° C. to convert the portion of the second metal layer adjacent to the barrier metal silicide into the second metal silicide. When the second metal layer is titanium (Ti), cobalt (Co), nickel (Ni) or tungsten (W), the second metal silicide formed on the barrier metal silicide in step 240 may be a titanium silicide (TiSi), a cobalt silicide (CoSi), a nickel silicide (NiSi) or a tungsten silicide (WSi). The presence of the barrier metal silicide prevents metal atoms from the second metal layer from diffusing into the underlying silicon-containing layer during the second heat treatment and forming a metal silicide layer within the underlying silicon-containing layer.

The method 200 further includes forming a metal plug above and in electrical communication with the second metal layer, the second metal silicide, the barrier metal silicide and the underlying silicon-containing layer (in step 250). The metal plug may include a wide variety of metal materials, such as aluminum (Al), copper (Cu), tungsten (W), molybdenum (Mo), ruthenium (Ru), etc. In some embodiments, the method 200 may perform an optional nitridation process to convert an upper surface of the second metal layer into a metal nitride layer prior to forming the metal plug in step 250, so that the metal plug is formed in contact with the metal nitride layer. In one example embodiment, a Ru metal plug may be formed in contact with the metal nitride layer. The optional nitridation process may be performed when the second metal layer comprises metals that are easily oxidized. For example, when titanium (Ti) is used for the second metal layer, a nitridation process may be performed to convert an upper surface of the titanium (Ti) layer into titanium nitride (TiN), which prevents oxidation of the underlying titanium metal. However, the nitridation process may be omitted when metals that are not easily oxidized (such as, e.g., tungsten) are used in the second metal layer.

The method 200 shown in FIG. 2 utilizes an improved silicidation process to reduce the contact resistivity of a metal silicide-to-semiconductor contact formed between an overlying metal plug and an underlying silicon-containing layer. The underlying silicon-containing layer may include a wide variety of doped and undoped silicon-containing materials such as, but not limited to, amorphous silicon (a-Si), polycrystalline silicon (poly-Si), silicon carbide (SiC), carbon-doped silicon, silicon germanium (SiGe), germanium-doped silicon, etc. In some embodiments, the underlying silicon-containing layer may include an n-type silicon material, such as silicon (Si) doped with arsenic (As) or phosphorus (P), when the silicidation process disclosed herein is used to fabricate an nMOSFET device. In other embodiments, the underlying silicon-containing layer may include a p-type silicon material, such as silicon (Si) doped with boron (B) or gallium (Ga), when the silicidation process is used to fabricate a pMOSFET device. As such, the underlying silicon-containing layer may include a variety of silicon-containing materials used to form the source, drain and/or gate regions of a MOSFET device.

In the silicidation process disclosed herein, a thin barrier metal silicide (e.g., a zirconium silicide (ZrSi) or a hafnium silicide (HfSi) having a thickness ≤10 nm, ≤2 nm or ≤1 nm) is formed on the underlying silicon-containing layer (in step 220) before a thicker metal layer (e.g., a titanium (Ti) layer, nickel (Ni) layer, cobalt (Co) layer, tungsten (W) layer, etc., having a thickness ranging between 2 nm to 15 nm) is deposited on the barrier metal silicide (in step 230) and heated to form a second metal silicide (e.g., a titanium silicide (TiSi), nickel silicide (NiSi), cobalt silicide (CoSi), tungsten silicide (WSi), etc.) above the barrier metal silicide (in step 240). Together, the barrier metal silicide and the second metal silicide provide a lower contact resistivity between the metal plug and the underlying silicon-containing layer than would otherwise be provided with the second metal silicide alone. Thus, the barrier metal silicide and the second metal silicide provide a metal silicide-to-semiconductor contact between the metal plug and the underlying silicon-containing layer with reduced contact resistivity.

In some embodiments, the barrier metal silicide formed in step 220 may reduce the contact resistivity between the metal plug and the underlying silicon-containing layer by providing a lower Schottky barrier height (SBH) than the SBH provided by the second metal silicide alone. For example, zirconium silicide has been shown to provide a Schottky barrier height of 0.55 eV on n-type silicon. This is lower than the SBH (e.g., 0.61 eV) of titanium silicide (TiSi) on n-type silicon and one of the lowest Schottky barrier heights among refractory metal silicides. Thin zirconium silicides are also known to provide relatively low film resistivity. For example, zirconium silicides less than 2 nm thick may provide a lower film resistivity than a 2 nm thick titanium silicide. Other metal silicides, such as hafnium silicides, also provide relatively low SBH and film resistivity, and thus, may be used in the improved silicidation process disclosed herein to reduce contact resistivity of a metal silicide-to-semiconductor contact.

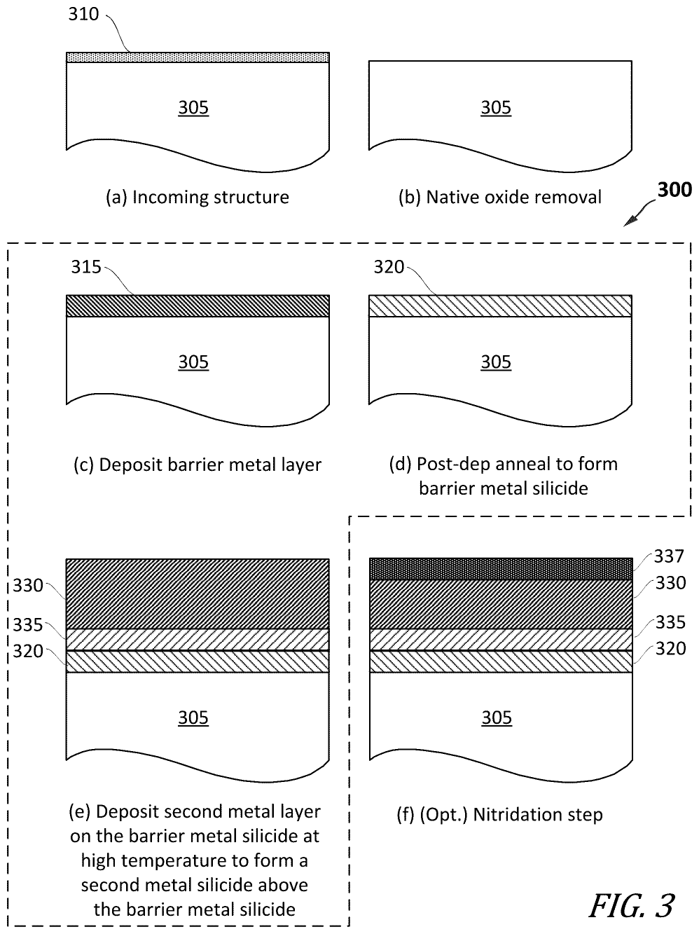

FIG. 3 provides cross-sectional views through a portion of a semiconductor device, illustrating an improved silicidation process 300 in accordance with one embodiment of the present disclosure. In some embodiments, a native oxide 310 may be removed from an exposed surface of a semiconductor material 305 included within the semiconductor device in steps (a)-(b) before the silicidation process 300 is performed in steps (c)-(e). The semiconductor material 305 may include a wide variety of doped and undoped silicon-containing materials, as discussed above. In some embodiments, a chemical oxide removal (COR) process may use any suitable wet chemistry to remove the native oxide 310 in step (b).

Once the native oxide 310 is removed, the silicidation process 300 may begin by depositing a relatively thin (e.g., ≤10 nm, ≤2 nm or ≤1 nm) barrier metal layer 315 on the exposed surface of the semiconductor material 305 (in step (c)). The barrier metal layer 315 and the semiconductor material 305 may then be annealed at a temperature greater than 400° C. to form a barrier metal silicide 320 on the semiconductor material 305 (in step (d)). During the post-deposition anneal step (d), silicon atoms from the semiconductor material 305 diffuse into the barrier metal layer 315 to form the barrier metal silicide 320. Since the barrier metal layer 315 is relatively thin, a majority (or entirety) of the barrier metal layer 315 is converted into the barrier metal silicide 320 during the post-deposition anneal.

After the barrier metal silicide 320 is formed, the silicidation process 300 may deposit a relatively thick (e.g., 2 nm to 15 nm) second metal layer 330 on the barrier metal silicide 320 (in step (e)). In the embodiment shown in FIG. 3, the second metal layer 330 is deposited at a relatively high temperature (e.g., a temperature ranging between 300° C. and 550° C.). During the deposition step (e), silicon atoms from the barrier metal silicide 320 diffuse into a lower surface of the second metal layer 330 to form a second metal silicide 335 above and in contact with the barrier metal silicide 320. Since the second metal layer 330 is relatively thick, only a portion of the second metal layer 330 adjacent to the barrier metal silicide 320 is converted into the second metal silicide 335 during the deposition step (e). In some embodiments, an optional nitridation process may be performed in step (f) to convert an upper surface of the second metal layer 330 into a metal nitride layer 337. As noted above, nitridation of the upper surface of the second metal layer 330 may be beneficial when the second metal layer 330 is easily oxidized.

The second metal layer 330 deposited in step (e) may include a wide variety of metals used to form metal silicides in semiconductor devices. For example, the second metal layer 330 may include titanium (Ti), cobalt (Co), nickel (Ni), tungsten (W), molybdenum (Mo), ruthenium (Ru), tantalum (Ta), chromium (Cr), rhodium (Rh), iridium (Ir), palladium (Pd), platinum (Pt), osmium (Os), hafnium (Hf), yttrium (Y), lanthanum (La), etc. The second metal layer 330 deposited in step (e), and the second metal silicide 335 formed during the deposition step (e), may generally depend on the semiconductor device being formed. For example, titanium silicide (TiSi), cobalt silicide (CoSi), nickel silicide (NiSi) and tungsten silicide (WSi) are commonly used to form metal silicide-to-semiconductor contacts in the source, drain and gate regions of MOSFET devices. In some embodiments, the same metal silicide may be used to form metal silicide-to-semiconductor contacts in n-type MOSFET (nMOSFET) and p-type MOSFET (pMOSFET) devices. In other embodiments, contact resistance may be reduced by utilizing: (a) lower work function metals, such as titanium (Ti, 4.33 eV) and tungsten (W, 4.32-4.55 eV), to form metal silicide-to-semiconductor contacts in nMOSFET devices, and (b) higher work function metals, such as cobalt (Co, 5.0 eV) and nickel (Ni, 5.15 eV), to form metal silicide-to-semiconductor contacts in pMOSFET devices.

The barrier metal layer 315 deposited in step (c) may also include a wide variety of work function metals, depending on the semiconductor device being formed. When fabricating an nMOSFET device, for example, a metal with a lower work function than that of the second metal layer 330 (e.g., titanium (Ti), 4.33 eV, tungsten (W), 4.32-4.55 eV, cobalt (Co), 5.0 eV, nickel (Ni), 5.15 eV) may be used within the barrier metal layer 315 to reduce contact resistivity of the subsequently formed nMOSFET source, drain and gate contacts. For example, manganese (Mn, 4.1 eV), indium (In, 4.09 eV), zirconium (Zr, 4.05 eV), tantalum (Ta, 4.0-4.8 eV), niobium (Nb, 3.95-4.87 eV), hafnium (Hf, 3.9 eV), magnesium (Mg, 3.66 eV), zinc (Zn, 3.63-4.9 eV), etc., may be used within the barrier metal layer 315 when fabricating nMOSFET contacts. Selecting a barrier metal layer 315 with a lower work function than the second metal layer 330 reduces the contact resistivity of nMOSFET source, drain and gate contacts by reducing the SBH of the metal silicide-to-semiconductor contact formed between the overlying metal plug and the underlying source, drain or gate regions of the nMOSFET device.

When fabricating a pMOSFET device, a metal having a higher work function than that of the second metal layer 330 (e.g., titanium (Ti), 4.33 eV, tungsten (W), 4.32-4.55 eV, cobalt (Co), 5.0 eV, nickel (Ni), 5.15 eV) may be used within the barrier metal layer 315 to reduce contact resistivity of the subsequently formed pMOSFET source, drain and gate contacts. For example, tungsten (W, 4.32-4.55 eV), ruthenium (Ru, 4.71 eV), molybdenum (Mo, 4.36-4.95), copper (Cu, 4.53-5.1), rhodium (Rh, 4.98 eV), iridium (Ir, 5.0-5.7 eV), palladium (Pd, 5.22-5.6 eV), platinum (Pt, 5.12-5.93 eV), osmium (Os, 5.93 eV), etc., may be used within the barrier metal layer 315 when fabricating pMOSFET contacts. Selecting a barrier metal layer 315 with a higher work function than that of the second metal layer 330 reduces the contact resistivity of pMOS source, drain and gate contacts by increasing the SBH of the metal silicide-to-semiconductor contact formed between the overlying metal plug and the underlying source, drain or gate regions of the pMOSFET device.

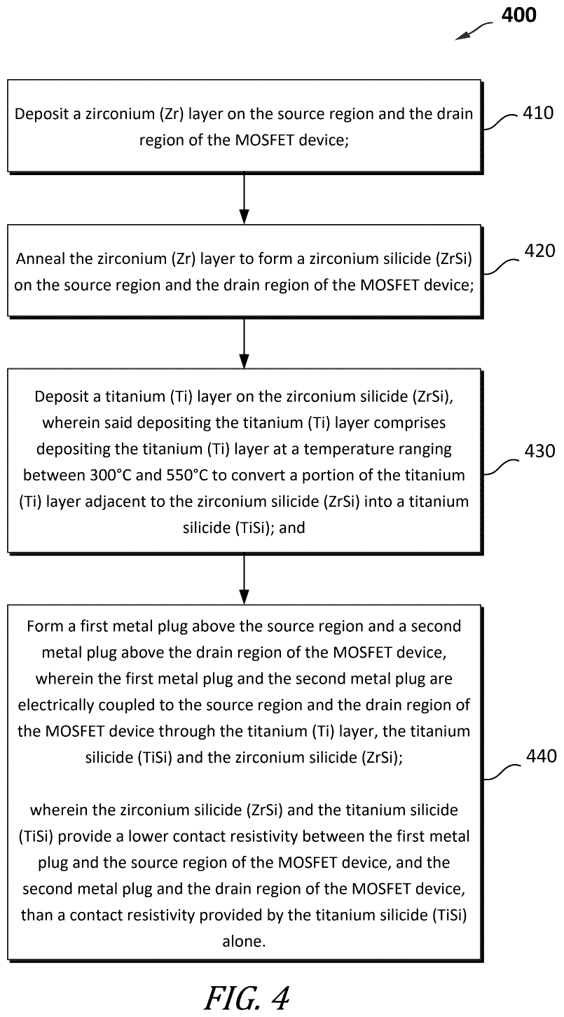

FIG. 4 is a flowchart diagram illustrating one embodiment of a method 400 that utilizes the techniques disclosed herein to reduce contact resistivity in a metal oxide semiconductor field effect transistor (MOSFET) device having a gate structure, a source region and a drain region. In some embodiments, the method 400 may be used to reduce contact resistivity in an nMOSFET device. It will be recognized that the embodiment of the method 400 is merely exemplary and additional methods may utilize the techniques disclosed herein to reduce contact resistance in other semiconductor devices, such as pMOSFET devices. Further, additional processing steps may be added to the method 400 as the steps described are not intended to be exclusive. Moreover, the order of the steps is not limited to the order shown in the figures as different orders may occur and/or various steps may be performed in combination or at the same time.

As shown in FIG. 4, the method 400 may generally begin by depositing a zirconium (Zr) layer on the source region and the drain region of the MOSFET device (in step 410). The zirconium (Zr) layer deposited in step 410 may be a relatively thin layer having a deposition thickness less than or equal to 10 nm, less than or equal to 2 nm or less than or equal to 1 nm. After deposition, the Zr layer is annealed to form a zirconium silicide (ZrSi) on the source region and the drain region of the MOSFET device (in step 420). During the anneal step, the zirconium (Zr) layer, the source region and the drain region of the MOSFET device are exposed to a temperature ranging between 400° C. and 550° C. to convert the zirconium (Zr) layer into the zirconium silicide (ZrSi).

After forming the zirconium silicide (ZrSi) on the source region and the drain region of the MOSFET device, the method 400 deposits a titanium (Ti) layer on the zirconium silicide (ZrSi) (in step 430) and forms a first metal plug above the source region and a second metal plug above the drain region of the MOSFET device (in step 440). In the embodiment shown in FIG. 4, the titanium (Ti) layer is deposited at a temperature ranging between 300° C. and 550° C. to convert a portion of the titanium (Ti) layer adjacent to the zirconium silicide (ZrSi) into a titanium silicide (TiSi). However, other embodiments may utilize a lower deposition temperature and a post-deposition anneal to form the titanium silicide (TiSi). The first metal plug and the second metal plug are electrically coupled to the source region and the drain region of the MOSFET device through at least the titanium (Ti) layer, the titanium silicide (TiSi) and the zirconium silicide (ZrSi). In some embodiments, the method 400 may perform a nitridation process to convert an upper surface of the titanium (Ti) layer into a titanium nitride (TiN) layer prior to forming the first metal plug and the second metal plug, so that the first metal plug and the second metal plug are formed in contact with the titanium nitride (TiN) layer. The first/second metal plugs may include a wide variety of metal materials, such as aluminum (Al), copper (Cu), tungsten (W), molybdenum (Mo), ruthenium (Ru), etc., as discussed above.

In the method 400 shown in FIG. 4, the zirconium silicide (ZrSi) and the titanium silicide (TiSi) provide a lower contact resistivity between the first metal plug and the source region of the MOSFET device, and the second metal plug and the drain region of the MOSFET device, than a contact resistivity provided by the titanium silicide (TiSi) alone. As noted above, the zirconium silicide formed in step 420 reduces contact resistivity by providing a lower SBH (0.55 eV) than the SBH (0.61 eV) of titanium silicide (TiSi) on n-type silicon. The zirconium silicide (ZrSi) also prevents titanium atoms from the titanium (Ti) layer from diffusing into the source and drain region of the MOSFET device during the subsequently performed titanium deposition step 420.

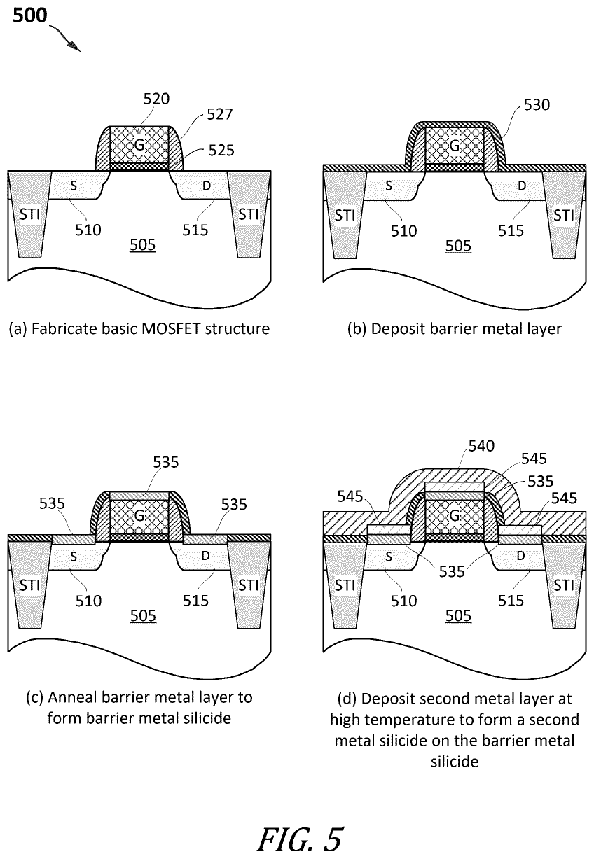

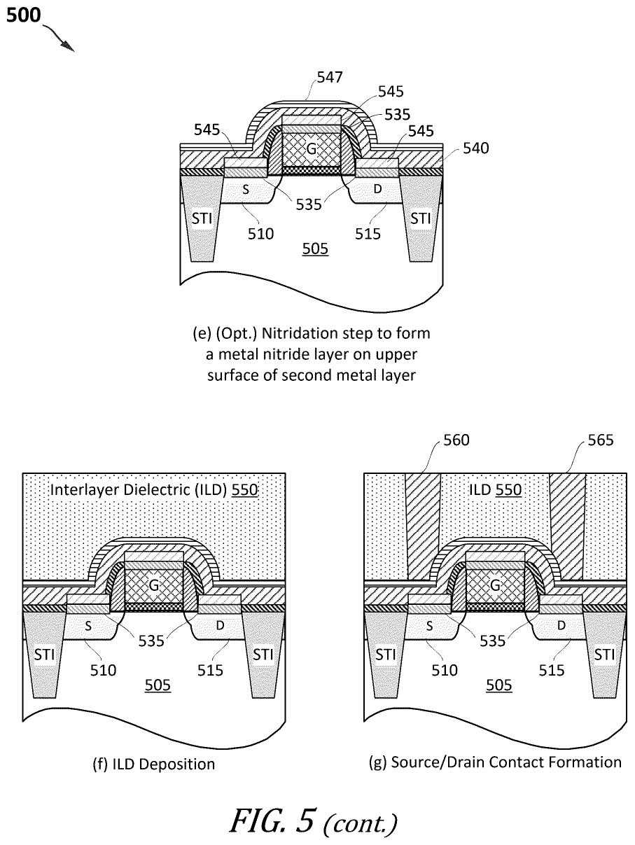

FIG. 5 illustrates one embodiment of a process flow 500 that utilizes the techniques disclosed herein to reduce contact resistivity in a MOSFET device. Cross-sectional views of a MOSFET device are used in FIG. 5 to illustrate the process flow 500. It is recognized that the various structures and layers used to form the MOSFET device are not drawn to scale in FIG. 5. In particular, the silicide regions formed above the gate structure and source/drain regions of the MOSFET device are exaggerated to better illustrate the inventive concepts disclosed herein.

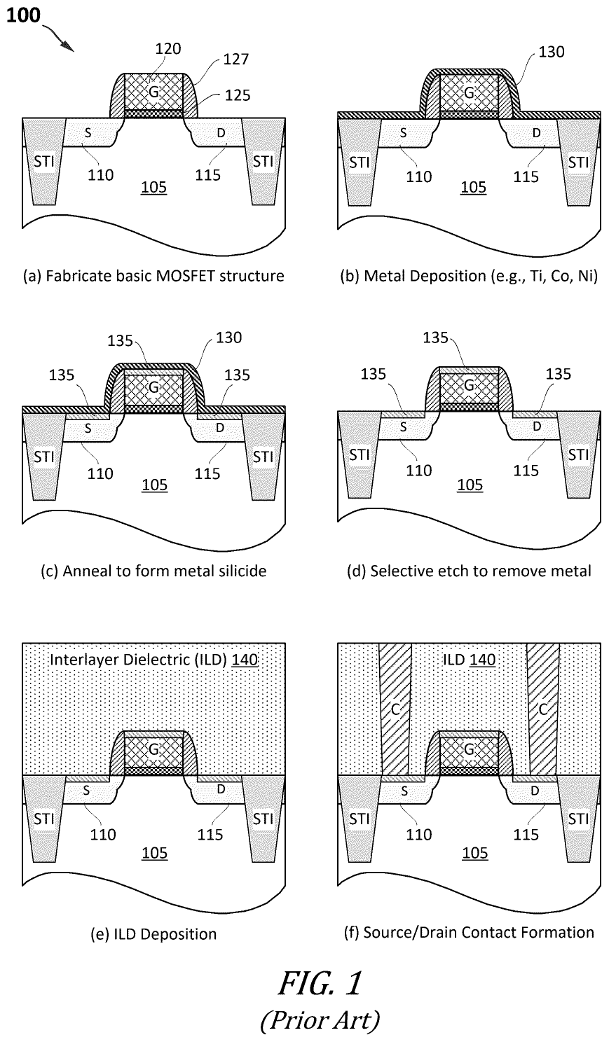

Like the conventional process flow 100 shown in FIG. 1, the process flow 500 may begin with the fabrication of a basic MOSFET structure on/within a silicon-based substrate in step (a). As shown in FIG. 5, the MOSFET device includes a source (S) region 510 and a drain (D) region 515 formed within a silicon-based substrate 505 (e.g., Si, SiGe, SiC, etc.) and a gate structure formed above the source/drain (S/D) regions of the MOSFET device. The source region 510 and drain region 515 may be doped with various impurities, depending on the MOSFET device being formed. For example, the source/drain regions may include an n-type silicon material when fabricating an nMOSFET device, or a p-type silicon material when fabricating a pMOSFET device. The gate structure may generally include a conductive gate (G) layer 520 (e.g., a polysilicon gate) formed above a thin gate oxide 525. Gate spacers 527 are formed on sidewalls of the gate structure to electrically isolate the gate structure from the source/drain contacts subsequently formed in step (i). Shallow trench isolation (STI) regions are provided within the silicon-based substrate 505 to prevent current leakage between adjacent semiconductor devices.

After the basic MOSFET structure is formed in step (a), a barrier metal layer 530 is conformally deposited onto the MOSFET device in step (b). The barrier metal layer 530 may include a wide variety of work function metals, depending on the semiconductor device being formed. For example, the barrier metal layer 530 may include: (a) a relatively low work function metal (such as, e.g., Mn, In, Zr, Ta, Nb, Hf, Mg or Zn) when fabricating an nMOSFET device, or (b) a relatively high work function metal (such as, e.g., W, Ru, Mo, Cu, Rh, Ir, Pd, Pt or Os) when fabricating a pMOSFET device. In one example embodiment, the barrier metal layer 530 may include a relatively thin (e.g., ≤10 nm, ≤2 nm or ≤1 nm) layer of zirconium (Zr, 4.05 eV) when an nMOSFET device is formed. However, the barrier metal layer 530 is not limited to zirconium, and may include other low/high work function metals, as discussed above.

After barrier metal deposition, a high temperature anneal process is performed in step (c) to form barrier metal silicides at the interface between the barrier metal layer 530 and the gate (G), source (S) and drain (D) regions of the MOSFET device. During the anneal step, the substrate is exposed to a temperature high enough (e.g., a temperature ranging between 400-550° C.) to cause silicon atoms from the polysilicon of the gate layer 520 and the silicon within the source region 510 and the drain region 515 to diffuse into the barrier metal layer 530, thereby forming barrier metal silicides 535 above the source, drain and gate regions of the MOSFET device.

After formation of the barrier metal silicides 535 in step (c), the process flow 500 conformally deposits a relatively thick (e.g., 2 nm to 15 nm) second metal layer 540 on the MOSFET device at a relatively high temperature (e.g., a temperature ranging between 300° C. and 550° C.) in step (d). The second metal layer 540 may include a wide variety of work function metals, depending on the semiconductor device being formed. For example, the second metal layer 540 may include: (a) a relatively low work function metal (such as, e.g., Ti, TiN or W) when fabricating an nMOSFET device, or (b) a relatively high work function metal (such as, e.g., Ni or Co) when fabricating a pMOSFET device. In one example embodiment, the second metal layer 540 may include a relatively thick (e.g., 2 nm to 15 nm) layer of titanium (Ti, 4.33 eV) when an nMOSFET device is formed. However, the second metal layer 540 is not limited to titanium, and may include other low/high work function metals, as discussed above.

During the deposition step (d), silicon atoms from the barrier metal silicides 535 diffuse into a lower surface of the second metal layer 540 to form a second metal silicide 545 above and in contact with the barrier metal silicides 535. Since the second metal layer 540 is relatively thick, only a portion of the second metal layer 540 adjacent to the barrier metal silicides 535 is converted into the second metal silicide 545 during the deposition step (d). In some embodiments, a selective etch (not shown) may be performed to remove the portions of the second metal layer 540 not overlying the source, drain and gate regions of the MOSFET device. When the second metal layer 540 is formed from easily oxidized materials (such as titanium), a nitridation process may be performed in step (e) to convert an upper surface of the second metal layer 540 into a metal nitride layer 547. However, the nitridation step (e) may be omitted when the second metal layer 540 is formed from materials that resist oxidization (such as titanium nitride, tungsten, etc.).

In some embodiments, the process flow 500 may continue by depositing an interlayer dielectric layer (ILD) 550 on the MOSFET device in step (f) and etching the ILD 550 to form contact holes or vias to the metal silicides formed on/above the source region 510 and the drain region 515 of the MOSFET device. The contact holes or vias may be subsequently filled with a metal material (e.g., copper (Cu), tungsten (W), ruthenium (Ru), etc.) in step (g) to form a first metal plug 560 in electrical communication with the metal silicides of the source region 510 and a second metal plug 565 in electrical communication with the metal silicides of the drain region 515. Although not shown in FIG. 5, a third metal plug may be formed in in electrical communication with the metal silicide formed above the gate region by etching a contact hole within the ILD 550 and subsequently filling the contact hole with a metal material.

The metal silicides provided within the source, drain and gate regions of the MOSFET device reduce the contact resistance between the bulk metal of the metal plugs 560/565 and the underlying silicon included within the source, drain and gate regions of the MOSFET device. Compared to the conventional process flow 100 shown in FIG. 1, contact resistance is further reduced in the process flow 500 by forming thin barrier metal silicides 535 (e.g., a zirconium silicide (ZrSi) or hafnium silicide (HfSi) having a thickness ≤10 nm, ≤2 nm or ≤1 nm) on the underlying silicon (in step (b)) before a thicker metal layer (e.g., a titanium (Ti) layer, nickel (Ni) layer, cobalt (Co) layer, tungsten (W), etc., having a thickness ranging between 2 nm to 15 nm) is deposited on the barrier metal silicides 535 (in step 230) and heated to form a second metal silicide 545 (e.g., a titanium silicide (TiSi), nickel silicide (NiSi), cobalt silicide (CoSi), tungsten silicide (WSi), etc.) above the barrier metal silicides 535 (in step (e)). Together, the barrier metal silicides 535 and the second metal silicide 545 provide a lower contact resistivity between the metal plugs 560/565 and the underlying silicon than would otherwise be provided with the second metal silicide 545 alone. Thus, the barrier metal silicides 535 and the second metal silicide 545 provide a metal silicide-to-semiconductor contact between the metal plugs 560/565 and the underlying silicon with reduced contact resistivity.

The present disclosure provides various embodiments of methods and process flows for reducing contact resistance in a semiconductor device having at least one contact structure. In the embodiments disclosed herein, the at least one contact structure includes a metal plug formed above an underlying silicon-containing layer and a silicide region formed between the metal plug and the underlying silicon-containing layer. In example embodiments, the silicide region includes: (i) a zirconium silicide (ZrSi) having a thickness less than 10 nm formed on the underlying silicon-containing layer, and (ii) a titanium silicide (TiSi) having a thickness less than 10 nm formed on the zirconium silicide (ZrSi). Together, the zirconium silicide (ZrSi) and the titanium silicide (TiSi) provide a lower contact resistivity between the metal plug and the underlying silicon-containing layer than a contact resistivity provided by the titanium silicide (TiSi) alone.

The techniques disclosed in the present disclosure can be used to reduce the contact resistance of a metal silicide-to-semiconductor contact formed between an overlying metal plug and an underlying source, drain and/or gate region of a MOSFET device. However, one skilled in the art would recognize how the concepts disclosed herein could be used to reduce contact resistance in other semiconductor devices.

It is noted that various deposition processes can be used to form one or more of the material layers shown and described herein. For example, one or more depositions can be implemented using chemical vapor deposition (CVD), plasma enhanced CVD (PECVD), physical vapor deposition (PVD), atomic layer deposition (ALD), and/or other deposition processes. During the deposition process, a gas mixture including suitable gas chemistries can be used optionally in combination with one or more dilution gases (e.g., argon, nitrogen, etc.) at a variety of pressure, power, flow and temperature conditions to deposit the various metal layers described herein.

It is further noted that various etch processes can be used to etch one or more of the material layers shown and described herein. For example, one or more etch processes can be implemented using plasma etch processes, discharge etch processes, and/or other desired etch processes. During the etch process, a gas mixture including suitable gas chemistries can be used optionally in combination with one or more dilution gases (e.g., argon, nitrogen, etc.) at a variety of pressure, power, flow and temperature conditions to selectively etch the metal layers and/or the ILD described herein.

Other operating variables for process steps can also be adjusted to control the various deposition and/or etch processes described herein. The operating variables may include, for example, the chamber temperature, chamber pressure, flowrates of gases, types of gases, and/or other operating variables for the processing steps. Variations can also be implemented while still taking advantage of the techniques described herein.

Systems and methods for processing a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. In one embodiment, a MOSFET device may be formed on/within the substrate, as discussed further herein.

In some embodiments, the substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped, as discussed above.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for reducing contact resistivity in a semiconductor device, the method comprising:
depositing a barrier metal layer on an underlying silicon-containing layer, wherein the barrier metal layer comprises zirconium (Zr) or hafnium (Hf);
performing a first heat treatment during or after said depositing the barrier metal layer to convert the barrier metal layer into a barrier metal silicide, wherein the barrier metal silicide comprises a zirconium silicide (ZrSi) or a hafnium silicide (HfSi);
depositing a second metal layer on the barrier metal silicide, wherein the second metal layer comprises titanium (Ti), cobalt (Co), nickel (Ni) or tungsten (W);
performing a second heat treatment during or after said depositing the second metal layer to convert a portion of the second metal layer adjacent to the barrier metal silicide into a second metal silicide, wherein the second metal silicide comprises a titanium silicide (TiSi), a cobalt silicide (CoSi), a nickel silicide (NiSi) or a tungsten silicide (WSi); and
forming a metal plug above and in electrical communication with the second metal layer, the second metal silicide, the barrier metal silicide and the underlying silicon-containing layer;
wherein the barrier metal silicide and the second metal silicide provide a lower contact resistivity between the metal plug and the underlying silicon-containing layer than a contact resistivity provided by the second metal silicide alone.

2. The method of claim 1, wherein the barrier metal silicide reduces the contact resistivity between the metal plug and the underlying silicon-containing layer by providing a lower Schottky barrier height than a Schottky barrier height provided by the second metal silicide.

3. The method of claim 1, wherein the barrier metal silicide prevents metal atoms from the second metal layer from diffusing into the underlying silicon-containing layer during the second heat treatment and forming a metal silicide layer within the underlying silicon-containing layer.

4. The method of claim 1, wherein said depositing the barrier metal layer comprises depositing a zirconium (Zr) layer having a thickness less than 10 nm on the underlying silicon-containing layer.

5. The method of claim 4, wherein said performing the first heat treatment comprises exposing the zirconium (Zr) layer to a temperature ranging between 400° C. and 550° C. to convert the zirconium (Zr) layer into a zirconium silicide (ZrSi).

6. The method of claim 5, wherein said depositing the second metal layer comprises depositing a titanium (Ti) layer having a thickness ranging between 2 nm and 15 nm on the zirconium silicide (ZrSi).

7. The method of claim 6, wherein said performing the second heat treatment comprises exposing the titanium (Ti) layer to a temperature ranging between 300° C. and 550° C. to convert a portion of the titanium (Ti) layer adjacent to the zirconium silicide (ZrSi) into a titanium silicide (TiSi).

8. The method of claim 6, wherein prior to forming the metal plug, the method further comprises performing a nitridation process to convert an upper surface of the titanium (Ti) layer into a titanium nitride (TiN) layer.

9. The method of claim 8, wherein said forming the metal plug comprises forming the metal plug in contact with the titanium nitride (TiN) layer, wherein the metal plug comprises ruthenium (Ru), tungsten (W), copper (Cu) or aluminum (Al).

10. A method for reducing contact resistivity in a metal oxide semiconductor field effect transistor (MOSFET) device comprising a gate structure, a source region and a drain region, the method comprising:
depositing a zirconium (Zr) layer on the source region and the drain region of the MOSFET device;
annealing the zirconium (Zr) layer to form a zirconium silicide (ZrSi) on the source region and the drain region of the MOSFET device;
depositing a titanium (Ti) layer on the zirconium silicide (ZrSi), wherein said depositing the titanium (Ti) layer comprises depositing the titanium (Ti) layer at a temperature ranging between 300° C. and 550° C. to convert a portion of the titanium (Ti) layer adjacent to the zirconium silicide (ZrSi) into a titanium silicide (TiSi); and
forming a first metal plug above the source region and a second metal plug above the drain region of the MOSFET device, wherein the first metal plug and the second metal plug are electrically coupled to the source region and the drain region of the MOSFET device through the titanium (Ti) layer, the titanium silicide (TiSi) and the zirconium silicide (ZrSi);
wherein the zirconium silicide (ZrSi) and the titanium silicide (TiSi) provide a lower contact resistivity between the first metal plug and the source region of the MOSFET device, and the second metal plug and the drain region of the MOSFET device, than a contact resistivity provided by the titanium silicide (TiSi) alone.

11. The method of claim 10, wherein the zirconium silicide (ZrSi) reduces the contact resistivity between the first metal plug and the source region of the MOSFET device, and the second metal plug and the drain region of the MOSFET device, by providing a lower Schottky barrier height than a Schottky barrier height provided by the titanium silicide (TiSi).

12. The method of claim 10, wherein the zirconium silicide (ZrSi) prevents titanium atoms from the titanium (Ti) layer from diffusing into the source region and the drain region of the MOSFET device during said depositing the titanium (Ti) layer on the zirconium silicide (ZrSi).

13. The method of claim 10, wherein said depositing zirconium (Zr) layer comprises depositing the zirconium (Zr) layer to a thickness less than 10 nm on the underlying silicon-containing layer.

14. The method of claim 10, wherein said annealing the zirconium (Zr) layer comprises exposing the zirconium (Zr) layer to a temperature ranging between 400° C. and 550° C. to convert the zirconium (Zr) layer into the zirconium silicide (ZrSi).

15. The method of claim 10, wherein prior to forming the first metal plug above the source region and a second metal plug above the drain region of the MOSFET device, the method further comprises performing a nitridation process to convert the upper surface of the titanium (Ti) layer into a titanium nitride (TiN) layer.

16. The method of claim 15, wherein said forming the first metal plug above the source region and the second metal plug above the drain region of the MOSFET device comprises forming the first metal plug and the second metal plug in contact with the titanium nitride (TiN) layer, wherein the first metal plug and the second metal plug comprise ruthenium (Ru), tungsten (W), copper (Cu) or aluminum (Al).

17. A semiconductor device having at least one contact structure, the at least one contact structure comprising:
a metal plug formed above an underlying silicon-containing layer; and
a silicide region formed between the metal plug and the underlying silicon-containing layer, the silicide region comprising:
a zirconium silicide (ZrSi) formed on the underlying silicon-containing layer, the zirconium silicide (ZrSi) having a thickness less than 10 nm; and
a titanium silicide (TiSi) formed on the zirconium silicide (ZrSi), the titanium silicide (TiSi) having a thickness less than 10 nm;
wherein the zirconium silicide (ZrSi) and the titanium silicide (TiSi) provide a lower contact resistivity between the metal plug and the underlying silicon-containing layer than a contact resistivity provided by the titanium silicide (TiSi) alone.

18. The semiconductor device of claim 17, wherein the zirconium silicide (ZrSi) is formed by depositing a zirconium (Zr) layer having a thickness less than 10 nm on the underlying silicon-containing layer and heating the zirconium (Zr) layer to a temperature ranging between 400° C. and 550° C. to convert the zirconium (Zr) layer into the zirconium silicide (ZrSi).

19. The semiconductor device of claim 18, wherein the zirconium (Zr) layer is deposited to a thickness less than 2 nm.

20. The semiconductor device of claim 18, wherein the zirconium (Zr) layer is deposited to a thickness less than or equal to 1 nm.

21. The semiconductor device of claim 17, wherein the at least one contact structure further comprises a titanium (Ti) layer having a thickness ranging between 2 nm and 15 nm, wherein the titanium (Ti) layer is deposited on the zirconium silicide (ZrSi) and heated to a temperature ranging between 300° C. and 550° C., causing silicon atoms from the zirconium silicide (ZrSi) to diffuse into a lower surface of the titanium (Ti) layer to form the titanium silicide (TiSi) on the zirconium silicide (ZrSi).

22. The semiconductor device of claim 21, wherein the zirconium silicide (ZrSi) prevents titanium atoms from the titanium (Ti) layer from diffusing into the underlying silicon-containing layer when the titanium (Ti) layer is deposited on the zirconium silicide (ZrSi) and heated.

23. The semiconductor device of claim 21, wherein the at least one contact structure further comprises a titanium nitride (TiN) layer formed on an upper surface of the titanium (Ti) layer.

24. The semiconductor device of claim 23, wherein the metal plug is formed in contact with the titanium nitride (TiN) layer, and wherein the metal plug comprises ruthenium (Ru), tungsten (W), copper (Cu) or aluminum (Al).
